(19) United States
(12) Patent Application Publication
(10) Pub. No.: US 2025/0343391 A1
(43) Pub. Date: Nov. 6, 2025

(54) SEMICONDUCTOR OPTICAL DEVICE AND SEMICONDUCTOR OPTICAL DEVICE MANUFACTURING METHOD

(71) Applicant: FURUKAWA ELECTRIC CO., LTD., Tokyo (JP)

(72) Inventors: Kenichiro YAO, Tokyo (JP); Masahiro YOSHIDA, Tokyo (JP)

(73) Assignee: FURUKAWA ELECTRIC CO., LTD., Tokyo (JP)

(21) Appl. No.: 19/266,311

(22) Filed: Jul. 11, 2025

Related U.S. Application Data
(63) Continuation of application No. PCT/JP2024/004822, filed on Feb. 13, 2024.

(30) Foreign Application Priority Data
Feb. 14, 2023 (JP) 2023-020922

(51) Int. Cl. H01S 5/10; H01S 5/227

(52) U.S. Cl. CPC H01S 5/101; H01S 5/227

(57) ABSTRACT

A semiconductor optical device includes: a substrate expanding while intersecting with a first direction; and a layering portion layered on the substrate in the first direction, the layering portion including a plurality of semiconductor layers including a core layer. The layering portion includes a first waveguide structure and a second waveguide structure that are separated from each other in a second direction intersecting with the first direction and that are different from each other, in between the first waveguide structure and the second waveguide structure, a slit is formed that extends from surface of the layering portion to the substrate, and in bottom portion of the slit, a protruding portion is formed that extends along the slit and protrudes in the first direction.

This application is a continuation of International Application No. PCT/JP2024/004822, filed on Feb. 13, 2024 which claims the benefit of priority of the prior Japanese Patent Application No. 2023-020922, filed on Feb. 14, 2023, the entire contents of which are incorporated herein by reference.

### BACKGROUND

The present disclosure relates to a semiconductor optical device and a semiconductor optical device manufacturing method.

In the related art, a semiconductor optical device is known in which a plurality of waveguides having mutually different waveguide structures, such as waveguides having a buried mesa structure and waveguides having a high-mesa structure, is integrated onto a single substrate (For example, refer to WO2016/152274A1 and JP2021-27314A.

### SUMMARY

A semiconductor optical device of such a type is sometimes mounted on a platform using a flip-chip structure; or sometimes has another device, such as a temperature regulating device or a heatsink, mounted on its surface. However, according to the diligent research performed by the present inventor, in a conventional semiconductor optical device of the abovementioned type, sometimes protrusions are formed on the surface that is on the opposite side of the underside surface. If such protrusions are formed, there is a risk that the adhesiveness with respect to the mounting target undergoes a decline, or there is a risk that the height of the mounted semiconductor optical device does not match the planned height. For example, a decline in the adhesiveness with respect to the temperature regulating device could lead to a decline in the heat dissipation of the semiconductor optical device. Moreover, a mismatch in the height could lead to a mismatch in the optical positions with respect to the other devices on the platform. Furthermore, if the height of the protrusions increases excessively, then there is a risk that the mounting cannot be performed.

There is a need for a new and improved semiconductor optical device having improved feasibility of mounting and a semiconductor optical device manufacturing method for manufacturing that semiconductor optical device.

According to one aspect of the present disclosure, there is provided a semiconductor optical device including: a substrate expanding while intersecting with a first direction; and a layering portion layered on the substrate in the first direction, the layering portion including a plurality of semiconductor layers including a core layer, wherein the layering portion includes a first waveguide structure and a second waveguide structure that are separated from each other in a second direction intersecting with the first direction and that are different from each other, in between the first waveguide structure and the second waveguide structure, a slit is formed that extends from surface of the layering portion to the substrate, and in bottom portion of the slit, a protruding portion is formed that extends along the slit and protrudes in the first direction.

According to another aspect of the present disclosure, there is provided a semiconductor optical device manufacturing method including: forming a layering portion on a substrate expanding while intersecting with a first direction such that the layering portion is layered on the substrate in the first direction and includes a plurality of semiconductor layers including a core layer; and forming a slit that extends from surface of the layering portion to the substrate, wherein in the forming the layering portion, two pre-structures are formed at positions separated from each other in a second direction that intersects with the first direction, the two pre-structures serving as basis of a first waveguide structure and a second waveguide structure that are different from each other, and in the forming the slit, the slit is formed in a region that includes a protruding portion formed on surface of the layering portion in a region present in between the two pre-structures.

### BRIEF DESCRIPTION OF THE DRAWINGS

FIG. 1 is an illustrative and schematic cross-sectional view of a semiconductor optical device according to a first embodiment;

FIG. 2 is an illustrative and schematic planar view of the semiconductor optical device according to the first embodiment;

FIG. 3 is a diagram for explaining a semiconductor optical device manufacturing method for manufacturing the semiconductor optical device according to the first embodiment;

FIG. 4 is a diagram for explaining the semiconductor optical device manufacturing method for manufacturing the semiconductor optical device according to the first embodiment;

FIG. 5 is a diagram for explaining the semiconductor optical device manufacturing method for manufacturing the semiconductor optical device according to the first embodiment;

FIG. 6 is an illustrative and schematic cross-sectional view of a semiconductor optical device according to a second embodiment;

FIG. 7 is an illustrative and schematic planar view of the semiconductor optical device according to the second embodiment;

FIG. 8 is an illustrative and schematic cross-sectional view of a semiconductor optical device according to a third embodiment;

FIG. 9 is an illustrative and schematic cross-sectional view of a semiconductor optical device according to a fourth embodiment, and represents a diagram for explaining the use of the semiconductor optical device; and

FIG. 10 is an illustrative and schematic planar view of the semiconductor optical device according to the fourth embodiment.

### DETAILED DESCRIPTION

Exemplary embodiments are described below. The configurations explained in the embodiments described below as well as the actions and the results (effects) attributed to the configurations are only exemplary. Thus, the present disclosure may be implemented also using some different configuration than the configurations disclosed in the embodiments described below. Meanwhile, according to the present disclosure, it becomes possible to achieve at least one of various effects (including secondary effects) that are attributed to the configurations.

The embodiments below include identical constituent elements. Thus, based on the identical configuration according to each embodiment, it becomes possible to achieve identical actions and identical effects. In the following explanation, the identical constituent elements are referred to by the same reference numerals, and their explanation is not given in a repeated manner.

In the present written description, ordinal numbers are assigned only for convenience and with the aim of differentiating among the directions and the portions. Thus, the ordinal numbers neither indicate the priority or the sequencing nor restrict the count.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other. The X direction may be referred to as the longitudinal direction or the direction of extension. The Y direction may be referred to as the short direction or the width direction. The Z direction may be referred to as the layering direction or the height direction.

Meanwhile, the drawings are schematic diagrams intended for use in the explanation. Thus, in the drawings, the scale and the ratio does not necessarily match with the actual objects.

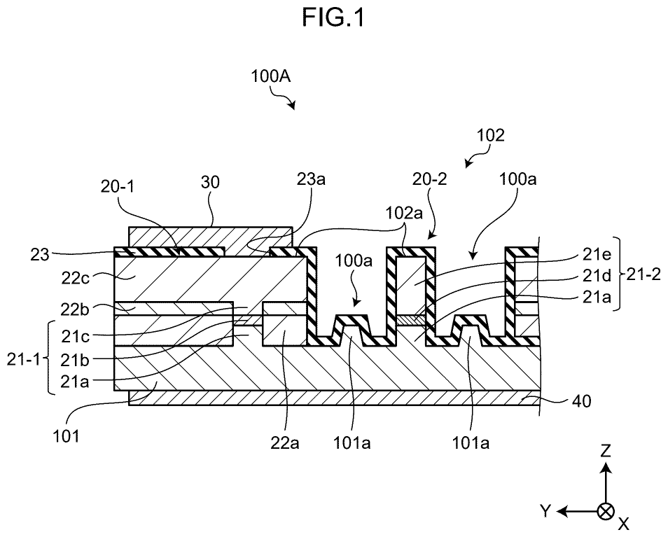

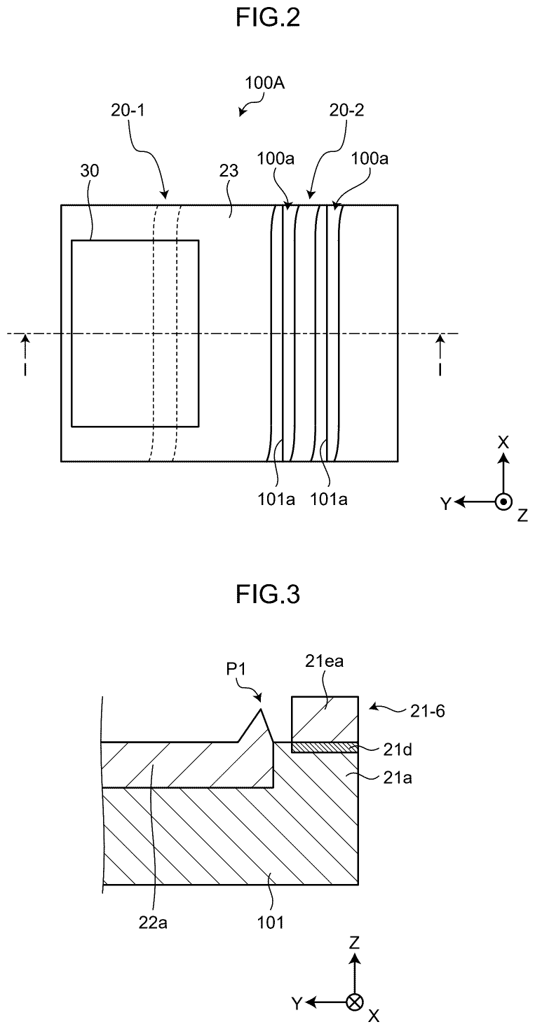

FIG. 1 is a cross-sectional view of a semiconductor optical device 100A according to a first embodiment. FIG. 2 is a planar view of the semiconductor optical device 100A. Herein, FIG. 1 is an I-I cross-sectional view of FIG. 2.

As illustrated in FIGS. 1 and 2, the semiconductor optical device 100A includes a substrate 101, a layering portion 102, an insulation layer 23, and electrodes 30 and 40. The layering portion 102 includes two waveguide structures 20-1 and 20-2. The waveguide structure 20-1 represents an example of a first waveguide structure, and the waveguide structure 20-2 represents an example of a second waveguide structure.

The substrate 101 has a substantially constant thickness in the Z direction and expands while intersecting with the Z direction. The substrate 101 is made of, for example, n-InP. The layers constituting the waveguide structure 20, the insulation layer 23, and the electrode 30 are layered on the substrate 101 in the Z direction according to a known semiconductor process. The Z direction may be referred to as the layering direction, the thickness direction, or the height direction. The Z direction represents an example of a first direction.

The electrode 40 is disposed on that surface of the substrate 101 which is on the opposite side of the Z direction. The electrode 40 has, for example, a layering structure including AuGe, Ni, and Au.

In the waveguide structure 20-1, on that surface of the substrate 101 which is on the opposite side of the electrode 40, a mesa 21-2 is formed that includes a cladding layer 21a, an active core layer 21b, and a cladding layer 21c. The cladding layer 21a, the active core layer 21b, and the cladding layer 21c are layered in that order on the substrate 101 in the Z direction. The mesa 21-1 extends in the X direction with a substantially constant width in the Y direction and a substantially constant height in the Z direction. The active core layer 21b represents an example of a core layer. The cladding layer 21a, the active core layer 21b, and the cladding layer 21c represent examples of a semiconductor layer.

The cladding layer 21a is layered on the substrate 101. The cladding layer 21a is made of, for example, n-InP. The active core layer 21b is layered on the cladding layer 21a. The active core layer 21b has a layering structure having, for example, n-InGaAsP. The cladding layer 21c is layered on the active core layer 21b. The cladding layer 21c is made of, for example, p-InP.

The mesa 21-1 is enclosed by current blocking layers 22a and 22b, which are adjacent to the mesa 21-1 in the Y direction and the opposite direction to the Y direction, and is enclosed by the cladding layer 22c that is adjacent to the mesa 21-1 in the Z direction. The current blocking layer 22a is made of, for example, p-InP; and the current blocking layer 22b is made of, for example, n-InP. The cladding layer 22c is made of, for example, p-InP. The waveguide structure 20-1 represents an example of a waveguide structure having a buried mesa structure.

The waveguide structure 20-1 is covered by the insulation layer 23. On the insulation layer 23, an opening 23a is formed at the position that overlaps with the mesa 21-1 in the Z direction. The insulation layer 23 is made of, for example, SiN. Meanwhile, the configuration of the waveguide structure 20-1 and the insulation layer 23 is not limited to the configuration explained above.

On the waveguide structure 20-1, the electrode 30 that is made of an electrical conductor is disposed on the opposite side of the substrate 101 with respect to the cladding layer 22c. The electrode 30 is a P-side electrode and is separated from the active core layer 21b in the Z direction. The electrode 30 makes contact with the cladding layer 22c via the opening 23a formed on the insulation layer 23. The electrodes 30 and 40 constitute an electrode pair meant for injecting an electrical current to the active core layer 21b.

The waveguide structure 20-1 having the configuration explained above may function as a semiconductor optical amplifier. The semiconductor optical amplifier performs optical amplification of the light input from one end of the active core layer 21b, and outputs the optically-amplified light from the other end of the active core layer 21b. Thus, the composition of the active core layer 21b is designed to enable optical amplification of the input light having a predetermined wavelength. The waveguide structure 20-1 that functions as a semiconductor optical amplifier represents an example of a first waveguide structure having an active function.

In the waveguide structure 20-2, on that surface of the substrate 101 which is on the opposite side of the electrode 40, a mesa 21-2 is formed that includes the cladding layer 21a, a waveguide core layer 21d, and a cladding layer 21e. The cladding layer 21a, the waveguide core layer 21d, and the cladding layer 21e are layered in that order on the substrate 101 in the Z direction. The mesa 21-2 extends in the X direction with a substantially constant width in the Y direction and a substantially constant height in the Z direction. The waveguide core layer 21d represents an example of the core layer. Moreover, the waveguide core layer 21d and the cladding layer 21e represent examples of a semiconductor layer.

The waveguide core layer 21d is layered on the cladding layer 21a. The waveguide core layer 21d is made of, for example, n-InGaAsP. The cladding layer 21e is layered on the waveguide core layer 21d. The cladding layer 21e is made of, for example, p-InP.

The waveguide structure 20-2 is configured to have a high-mesa waveguide structure due to the formation of two slits 100a that extend from a surface 102a of the layering portion 102 to the substrate 101. One of the two slits 100a represents an example of a slit formed between the first waveguide structure and the second waveguide structure.

The waveguide structure 20-2 is covered by the insulation layer 23.

The waveguide structure 20-2 having the configuration explained above functions as a waveguide that, for example, transmits most of the light input thereto from one end of the waveguide core layer 21d. Thus, the composition of the waveguide core layer 21d is designed to enable transmission of most of the input light, which has a predetermined wavelength, without absorbing that light. The waveguide structure 20-2 represents an example of a second waveguide structure having a passive function.

The two waveguide structures 20-1 and 20-2 extend in the X direction and guide the light in the X direction or in the opposite direction of the X direction. Moreover, the two waveguide structures 20-1 and 20-2 are separated from each other in the Y direction, and are arranged in the Y direction to sandwich one of the slits 100a therebetween. The Y direction represents an example of a second direction, and the X direction represents an example of a third direction.

As explained above, the waveguide structure 20-1 and 20-2 have partially different compositions of the semiconductor and have different waveguide structures. For that reason, the waveguide structures 20-1 and 20-1 are manufactured according to different semiconductor processes. The waveguide structures 20-1 and 20-2 represent examples of a first waveguide structure and a second waveguide structure, respectively, that are different from each other.

In the semiconductor optical device 100A, on the bottom surface of each slit 100a, a protruding portion 101a is formed that extends along the corresponding slit 100a and that protrudes in the Z direction. In the first embodiment, some portions of the substrate 101 constitute the protruding portions 101a. However, depending on the depth of the slits 100a, there are times when some portions of the substrate 101 and some portions of the cladding layer 21a constitute the protruding portions.

The formation of the protruding portions 101a may be attributed to the fact that the waveguide structures 20-1 and 20-2 are different from each other and are manufactured according to different semiconductor processes. In case the protruding portions 101a that protrude in the Z direction are present on the surface 102a of the layering portion 102, there are times when the feasibility of mounting of the semiconductor optical device 100A undergoes a decline.

In contrast, in the semiconductor optical device 100A, since the protruding portions 101a are formed in the bottom portions of the slits 100a, the protruding portions 101a may be easily prevented from protruding more in the Z direction than the surface 102a of the layering portion 102.

As explained above, according to the first embodiment, for example, it becomes possible to obtain a new and improved semiconductor optical device 100A that, for example, has excellent feasibility of mounting.

Given below is the explanation about an exemplary semiconductor optical device manufacturing method for manufacturing the semiconductor optical device 100A, and the explanation includes the reason behind the formation of the protruding portions 101a.

Firstly, a layering portion formation process is implemented. That is, on the entire surface of the wafer that includes the substrate 101; the cladding layer 21a, the active core layer 21b, and the cladding layer 21c are grown in a sequential manner. Then, in the waveguide structure 20-1, the region in which the active core layer 21b is kept intact and the corresponding surrounding region are masked using an etching mask; and the active core layer 21b and the cladding layer 21c in the remaining region are removed by etching. Subsequently, the etching mask is treated as the growth mask, and some portion of the waveguide core layer 21d and the cladding layer 21e is grown in that region in which removal-by-etching was performed. As a result, the active core layer 21b and the waveguide core layer 21d have the same position in the Z direction.

Then, the regions constituting the mesas 21-1 and 21-2 and the corresponding surrounding regions are etched into a mesa shape. The etching performed at that time includes etching into a mesa shape having a greater mesa width than the mesa widths of the mesas 21-1 and 21-2 in the Y direction. The mesa formed at that time is treated as a pre-mesa. Then, the etching mask is formed and etching is performed in such a way that the pre-mesa of the region constituting the mesa 21-1 has the equal mesa width to the mesa width of the mesa 21-1.

Then, the current blocking layer 22a is grown in order to bury the mesa 21-1. At that time, the pre-mesa of the region constituting the mesa 21-1 also gets buried in the current blocking layer 22a. However, during the growth, the current blocking layer 22a interferes with the waveguide core layer 21d that is already formed in the pre-mesa, and interferes with a cladding layer 21ea that is a part of the cladding layer 21e. Hence, it becomes difficult to have the current blocking layer 22a grow in a flat manner, and a protruding portion P1 gets formed at a position close to the pre-mesa 21-6 and along the pre-mesa 21-6 (see FIG. 3). The protruding portion P1 is prone to extending in the direction along the plane (0-1-1) in which atoms are easily incorporated particularly during the crystalline growth. The plane (0-1-1) is parallel to, for example, the orientation flat surface of the wafer that includes the substrate 101.

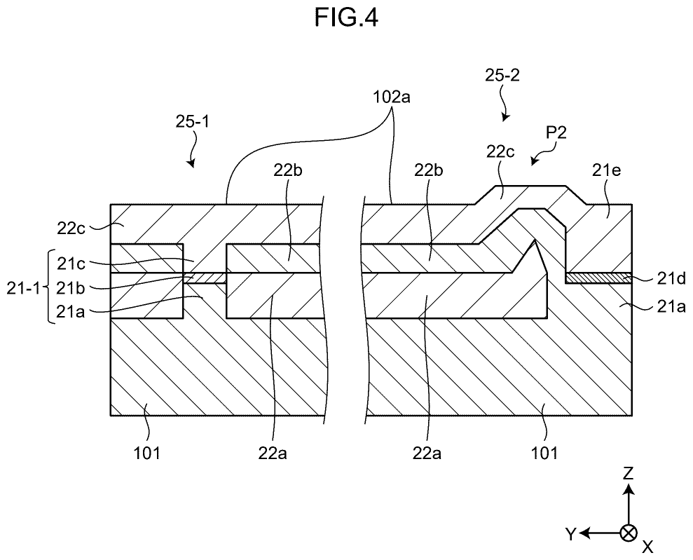

Subsequently, the remaining portions of the current blocking layer 22b, the cladding layer 22c, and the cladding layer 21e are grown; and the layering of the layering portion 102 is ended. At that time, on the surface 102a of the region in between two pre-structures 25-1 and 25-2, there remains a protruding portion P2 that results from the protruding portion P1 (see FIG. 4). The pre-structures 25-1 and 25-2 represent structures serving as the basis of the waveguide structures 20-1 and 20-2, respectively. The pre-structures 25-1 and 25-2 are formed at positions that are separated from each other in the Y direction.

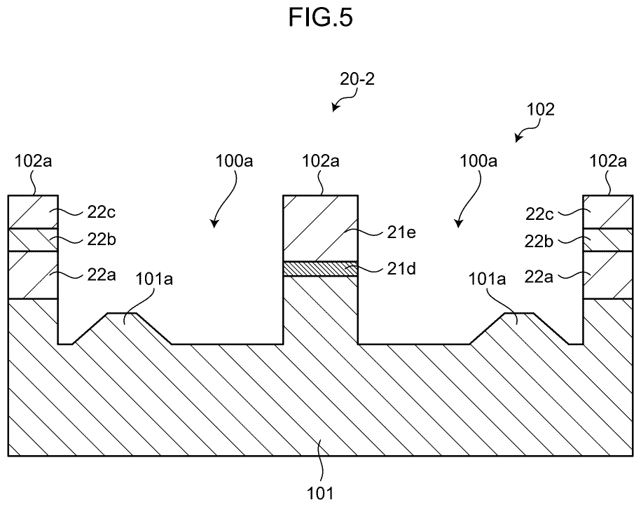

Subsequently, etching is performed on the layering portion 102, and the slits 100a are formed that extend from the surface 102a of the layering portion 102 to the substrate 101 (a slit formation process, see FIG. 5). At that time, the slits 100a are formed in the regions that include protruding portions formed on the surface 102a of the layering portion 102 in the region between the two pre-structures 25-1 and 25-2. Because of the slits 100a, the mesa shape of the waveguide structure 20-2 gets finalized. Moreover, since the slits 100a are formed in the region in which the protruding portion P2 is formed, the shape of the protruding portion P2 gets transferred onto the bottom portion of the slits 100a, and the protruding portions 101a are formed.

Then, the insulation layer 23 and the electrodes 30 and 40A are formed according to a known method, and the device is individualized from the wafer. Thus, the semiconductor optical device 100A reaches completion.

The semiconductor optical device 100A that is manufactured in the manner explained above represents, for example, a new and improved semiconductor optical device having excellent feasibility of mounting.

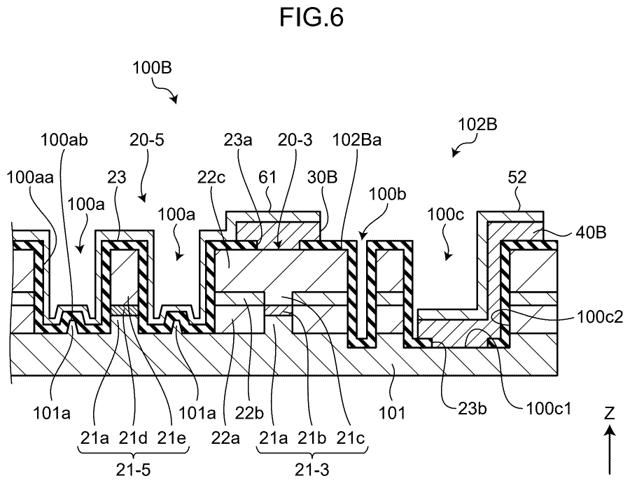

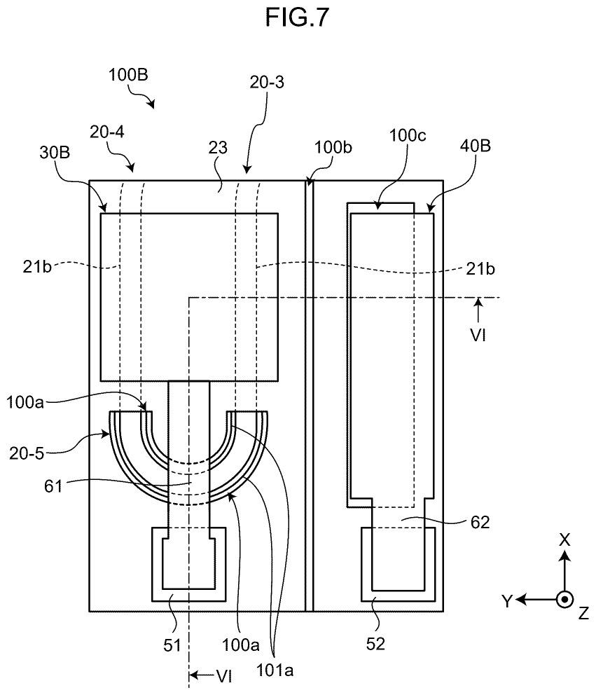

FIG. 7 is a planar view of a semiconductor optical device 100B according to the second embodiment. FIG. 6 is a VI-VI cross-sectional view of FIG. 7.

The semiconductor optical device 100B includes the substrate 101, a layering portion 102B, the insulation layer 23, electrodes 30B and 40B, electrode pads 51 and 52, and wirings 61 and 62. The layering portion 102B includes three waveguide structures 20-3, 20-4, and 20-5. The waveguide structures 20-3 and 20-4 represent examples of the first waveguide structure, and the waveguide structure 20-5 represents an example of the second waveguide structure.

The waveguide structure 20-3 has an identical configuration to the waveguide structure 20-1 according to the first embodiment, and includes a mesa 21-3. The waveguide structure 20-4 has an identical configuration to the waveguide structure 20-3. The waveguide structures 20-3 and 20-4 extend in the X direction. The waveguide structures 20-3 and 20-4 may function as, for example, semiconductor optical amplifiers. The waveguide structures 20-3 and 20-4 represent examples of a waveguide structure having a buried mesa structure, and represent examples of the first waveguide structure having an active function.

The electrode 30B is a P-side electrode used in common for injecting an electrical current to the waveguide structures 20-3 and 20-4.

The waveguide structure 20-5 has an identical configuration to the waveguide structure 20-2 according to the first embodiment, and includes a mesa 21-5. With respect to the waveguide structures 20-2 and 20-4, the waveguide structure 20-5 is disposed in the opposite direction of the X direction. The waveguide structure 20-5 has a U-shaped folded structure in the planar view; has one of the two end portions thereof connected to the waveguide structure 20-3; and has the other end portion thereof connected to the waveguide structure 20-4. As a result of having the two slits 100a, the waveguide structure 20-5 is treated as a high-mesa waveguide structure. In an identical manner to the semiconductor optical device 100A, in the semiconductor optical device 100B too, on the bottom portion of the slits 100a, the protruding portions 101a are formed that extend along the slits 100a and that protrude in the Z direction. The waveguide structure 20-5 represents an example of a waveguide structure that has a high-mesa structure and a folded structure, and represents an example of the second waveguide structure having a passive function.

The configuration of the electrode 40B, which represents the N-side electrode, is different than the configuration of the electrode 40 according to the first embodiment.

More particularly, in the semiconductor optical device 100B, on the opposite side of the waveguide structures 20-3 and 20-4 across a slit 100b, a depressed portion 100c is formed that is depressed in the opposite direction of the Z direction up to the substrate 101. The electrode 40B is disposed to run along a bottom surface 100cl and a side surface 100c2 of the depressed portion 100c. The slit 100b has the function of electrically insulating the electrode 30B from the electrode 40B.

On the insulation layer 23 that covers the depressed portion 100c, an opening 23b is formed at the position that overlaps with the bottom surface 100cl. The electrode 40B makes contact with the substrate 101 via the opening 23b.

The electrode pad 51 is disposed in the opposite direction of the X direction with respect to the waveguide structure 20-5. The electrode pad 51 is connected to an external power source using, for example, a bonding wire.

The wiring 61 is a wiring for electrically connecting the electrode pad 51 and the electrode 30B for the purpose of supplying the electrical current to the waveguide structures 20-3 and 20-4. The electrode 30B is disposed in the end portion of the layering portion 102B in the Z direction (i.e., disposed on the side of a surface 102Ba), and is electrically connected to the wiring 61. The wiring 61 extends in the X direction from the electrode pad 51 to the electrode 30B. At that time, midway, the wiring 61 runs along a side wall 100aa and a bottom surface 100ab of each slit 100a, and extends over the waveguide structure 20-5 and over the protruding portions 101a formed in the bottom portion of the slits 100a.

The electrode pad 52 is disposed in the opposite direction of the X direction with respect to the electrode 40B. The electrode pad 52 is connected to an external power source using, for example, a bonding wire.

The wiring 62 is a wiring for electrically connecting the electrode pad 51 and the electrode 40B for the purpose of supplying the electrical current to the waveguide structures 20-3 and 20-4. The wiring 62 extends from the electrode pad 52 to the electrode 40B in the X direction.

With such a configuration, the semiconductor optical device 100B entirely functions as a semiconductor optical amplifier. The semiconductor optical amplifier performs optical amplification of the light input from one end of the active core layer 21b of the waveguide structure 20-3, and outputs the optically-amplified light from one end of the active core layer 21b of the waveguide structure 20-4. The waveguide structure 20-5 guides the amplified light, which is amplified by the waveguide structure 20-3, to the waveguide structure 20-4.

In the case of a waveguide structure having a folded structure, such as in the case of the waveguide structure 20-5, the direction of extension of the waveguide structure 20-5 may be oriented in various directions with respect to the crystalline orientation. For that reason, it is difficult to ensure that the waveguide structure extends only in that direction in which the protruding portions 101a are not easily formed. In contrast, in the semiconductor optical device 100B according to the second embodiment, the protruding portions 101a are formed in the bottom portion of the slits 100a in an identical manner to the first embodiment. Hence, according to the second embodiment too, it becomes possible to achieve identical effects to the effects achieved according to the first embodiment.

Meanwhile, for example, when a wiring such as the wiring 61 is formed on the surface 102a on which the protruding portion P2 is formed as illustrated in FIG. 4; due to irregular crystalline growth, a proximal portion is present in which the current blocking layer 22a that is made of, for example, p-InP, comes close to the cladding layers 22c and 21e that are made of, for example, p-InP. In case the insulation layer 23 is not properly formed due to the protruding portions 101a thereby leading to a decline in the insulation properties and resulting in the establishment of electrical connection between the wiring 61 and the cladding layer 22c; there is a risk of occurrence of a leak path in the proximal portion. In contrast, in the semiconductor optical device 100B, since the protruding portions 101a are made of, for example, n-InP, it becomes possible to ensure that there is no occurrence of a leak path.

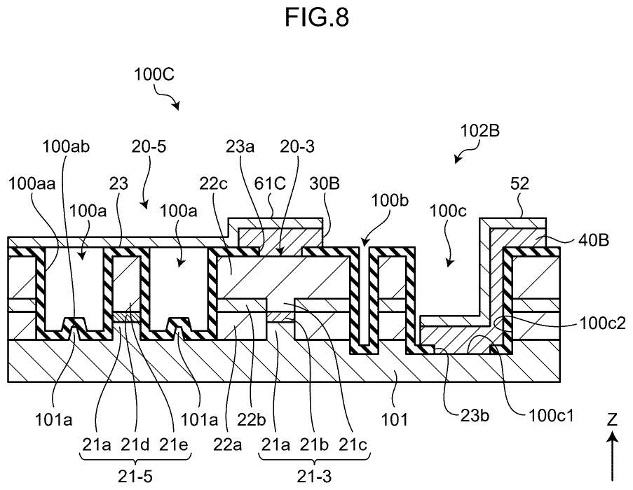

FIG. 8 is a planar view of a semiconductor optical device 100C according to a third embodiment.

The semiconductor optical device 100C includes a wiring 61C in place of the wiring 61 of the semiconductor optical device 100B. The wiring 61C differs from the wiring 61 in the way of being bridged over the slits 100a.

In the semiconductor optical device 100C according to the third embodiment too, the protruding portions 101a are formed in the bottom portion of the slits 100a in an identical manner to the first and second embodiments. Hence, according to the third embodiment too, it becomes possible to achieve identical effects to the effects achieved according to the first and second embodiments.

Moreover, in the semiconductor optical device 100B, since the wiring 61C is bridged over the slits 100a, even if the insulation layer 23 has poor insulation properties on the protruding portions 101a, the wiring 61C is at no risk of getting electrically connected to the semiconductor in the protruding portions 101a.

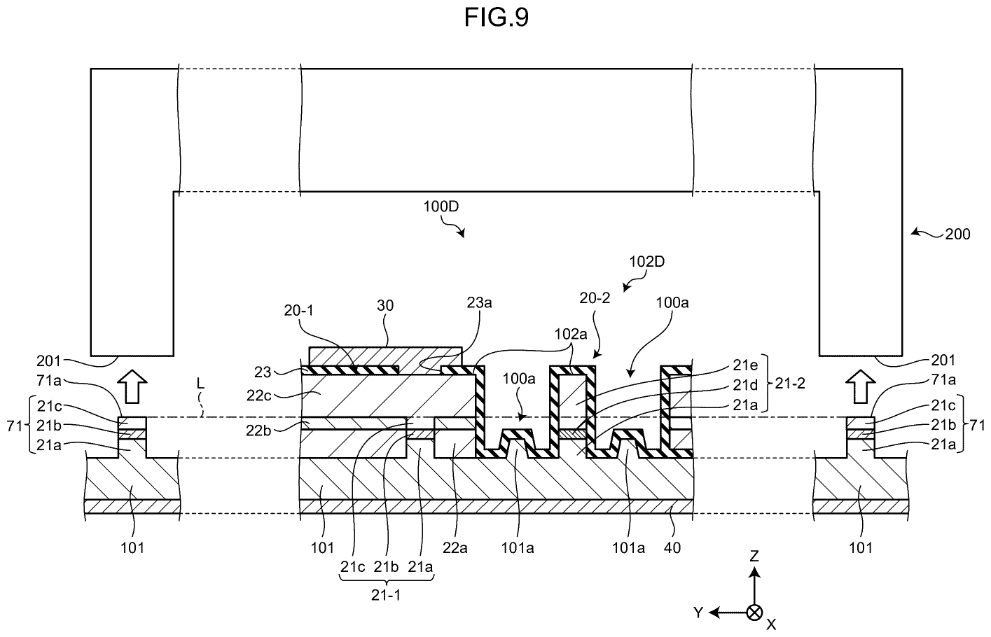

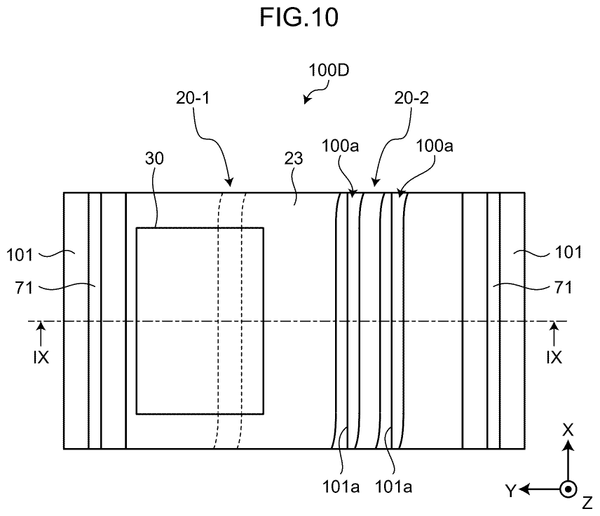

FIG. 9 is a cross-sectional view of a semiconductor optical device 100D (100) according to a fourth embodiment, and represents a diagram for explaining the use of the semiconductor optical device 100D (100). FIG. 10 is a planar view of the semiconductor optical device 100D (100). FIG. 9 is an IX-IX cross-sectional view of FIG. 10.

The semiconductor optical device 100D includes a layering portion 102D in place of the layering portion 102 of the semiconductor optical device 100A according to the first embodiment. The layering portion 102D is configured by adding two butting portions 71 in the layering portion 102. Thus, the layering portion 102D includes the two butting portions 71.

The two butting portions 71 protrude from the substrate 101 in the Z direction, and extend in the X direction with a substantially constant width in the Y direction and a substantially constant height in the Z direction. The two butting portions 71 are formed to sandwich the waveguide structure 20-1 in the Y direction.

The two butting portions 71 have the same layering structure as the layering structure of the mesa 21-1 of the waveguide structure 20-1. That is, the two butting portions 71 include the cladding layer 21a, the active core layer 21b, and the cladding layer 21c.

In the semiconductor optical device 100D according to the fourth embodiment, the protruding portions 101a are formed in the bottom portion of the slits 100a in an identical manner to the first to third embodiments. Hence, according to the fourth embodiment too, it becomes possible to achieve identical effects to the effects achieved according to the first to third embodiments.

In the semiconductor optical device 100D, the two butting portions 71 have the same layering structure as the layering structure of the mesa 21-1 of the waveguide structure 20-1. As a result, the height of an end surface 71a of each butting portion 71 in the Z direction from the substrate 101 has only small variability from the height of the active core layer 21b of the mesa 21-1 in the Z direction. As a result, the end surfaces 71a of the two butting portions 71 may be used as a highly accurate reference for the height of the active core layer 21b in the Z direction. Hence, for example, as illustrated in FIG. 9, in the case in which the semiconductor optical device 100D is to be mounted on a platform 200 made of silicon, the semiconductor optical device 100D and the platform 200 are bonded in such a way that the end surfaces 71a of the butting portions 71 abut against butting portions 201 of the platform 200, so that the height of the active core layer 21b of the mesa 21-1 may be matched with the height of the platform 200 with a high degree of accuracy. Thus, the optical-axis alignment of the optical devices such as the waveguides disposed on the platform 200 with the active core layer 21b of the mesa 21-1 may be performed with a high degree of accuracy.

The two butting portions 71 may be formed at the same time of forming the mesa 21-1 during the process of manufacturing the mesa 21-1 in the semiconductor optical device manufacturing method explained earlier.

While certain embodiments and modification examples have been described, these embodiments and modification examples have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure. Moreover, regarding the constituent elements, the specifications about the configurations and the shapes (structure, type, direction, shape, size, length, width, thickness, height, number, arrangement, position, material, etc.) may be suitably modified.

For example, in the embodiments described above, the first waveguide structure and the second waveguide structure have partially different compositions of the semiconductor and have different waveguide structures. When the first waveguide structure and the second waveguide structure are different from each other, the configuration is not limited to the embodiments described above. For example, when the first waveguide structure is formed on a platform made of silicon and when the second waveguide structure is formed by growing a different type of composite semiconductor than silicon on the same platform; the first waveguide structure and the second waveguide structure differ from each other.

In the second and third embodiments, the waveguide structure 20-5 representing an example of the second waveguide structure has a folded structure. Alternatively, the waveguide structures 20-3 and 20-4 representing examples of the first waveguide structure may have a folded structure. Moreover, at least either the first waveguide structure or the second waveguide structure may be an S-shaped waveguide structure in the planar view. An S-shaped waveguide structure represents an example of a folded structure.

In the embodiments described above, the waveguide structures 20-1, 20-3, and 20-4 have the optical amplification function as the active function. However, the active function of a first waveguide structure is not limited to the optical amplification function. Alternatively, for example, a first waveguide structure may have some other active function such as laser oscillation or optical modulation.

Meanwhile, the electrode 40 according to the first and fourth embodiments may be substituted with the configuration of the electrode 40B according to the second and third embodiments.

According to the present disclosure, for example, it becomes possible to achieve a new and improved semiconductor optical device having excellent feasibility of mounting, and to achieve a semiconductor optical device manufacturing method for manufacturing that semiconductor optical device.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor optical device comprising:
a substrate expanding while intersecting with a first direction; and
a layering portion layered on the substrate in the first direction, the layering portion including a plurality of semiconductor layers including a core layer, wherein
the layering portion includes a first waveguide structure and a second waveguide structure that are separated from each other in a second direction intersecting with the first direction and that are different from each other,
in between the first waveguide structure and the second waveguide structure, a slit is formed that extends from surface of the layering portion to the substrate, and
in bottom portion of the slit, a protruding portion is formed that extends along the slit and protrudes in the first direction.

2. The semiconductor optical device according to claim 1, wherein the first waveguide structure and the second waveguide structure extend in a third direction that intersects with the first direction and the second direction.

3. The semiconductor optical device according to claim 1, wherein at least either the first waveguide structure or the second waveguide structure has a folded structure.

4. The semiconductor optical device according to claim 1, wherein the first waveguide structure has an active function, and the second waveguide function has a passive function.

5. The semiconductor optical device according to claim 1, wherein the first waveguide structure has a buried mesa structure, and the second waveguide structure has a high-mesa structure.

6. The optical semiconductor device according to claim 1, further comprising a wiring that extends along a side wall and bottom surface of the slit, wherein
at least either the first waveguide structure or the second waveguide structure includes an electrode that is disposed at end portion of the layering portion in the first direction and that is electrically connected to the wiring.

7. The optical semiconductor device according to claim 1, further comprising a wiring that is bridged over the slit, wherein
at least either the first waveguide structure or the second waveguide structure includes an electrode that is disposed at end portion of the layering portion in the first direction and that is electrically connected to the wiring.

8. The semiconductor optical device according to claim 1, wherein
the layering portion includes two butting portions that are formed to sandwich the first waveguide structure in the second direction, and
the two butting portions have same layering structure as layering structure of a mesa of the first waveguide structure.

9. A semiconductor optical device manufacturing method comprising:
forming a layering portion on a substrate expanding while intersecting with a first direction such that the layering portion is layered on the substrate in the first direction and includes a plurality of semiconductor layers including a core layer; and
forming a slit that extends from surface of the layering portion to the substrate, wherein
in the forming the layering portion, two pre-structures are formed at positions separated from each other in a second direction that intersects with the first direction, the two pre-structures serving as basis of a first waveguide structure and a second waveguide structure that are different from each other, and
in the forming the slit, the slit is formed in a region that includes a protruding portion formed on surface of the layering portion in a region present in between the two pre-structures.
